(19) United States
(12) Patent Application Publication
(10) Pub. No.: US 2023/0105626 A1
(43) Pub. Date: Apr. 6, 2023

(54) SEMICONDUCTOR DEVICE AND METHOD FOR MANUFACTURING THE SAME

(71) Applicant: SHINDENGEN ELECTRIC MANUFACTURING CO., LTD., Tokyo (JP)

(72) Inventors: Koji ITO, Saitama (JP); Atsushi OGASAWARA, Saitama (JP); Ryota MURAI, Saitama (JP)

(21) Appl. No.: 17/730,462

(22) Filed: Apr. 27, 2022

(30) Foreign Application Priority Data
Oct. 5, 2021 (JP) 2021-164102

(51) Int. Cl. H01L 29/861; H01L 23/31; H01L 29/45; H01L 21/285; H01L 21/304; H01L 21/311; H01L 21/56; H01L 21/78; H01L 29/66

(52) U.S. Cl. CPC H01L 29/8613; H01L 23/3178; H01L 29/456; H01L 21/28568; H01L 21/3043; H01L 21/3046; H01L 21/31111; H01L 21/31144; H01L 21/56; H01L 21/78; H01L 29/66136

(57) ABSTRACT

The semiconductor device includes a mesa diode structure(20) and a protective layer(17b). The mesa diode structure includes, from bottom to top, a P-type semiconductor layer(11), a first N-type semiconductor layer(12), and a second N-type semiconductor layer(13) having a higher impurity concentration than the first N-type semiconductor layer. The protective layer is arranged on a side wall around the mesa diode structure seen in a plane. Specifically, the protective layer is arranged on an upper side surface(11c) of the P-type semiconductor layer and on side surfaces(12a,13a) of the first N-type semiconductor layer and the second N-type semiconductor layer, but is not arranged on a lower side surface of the P-type semiconductor layer. A bevel angle(30) of a PN junction plane between the P-type semiconductor layer and the first N-type semiconductor layer to the upper side surface of the P-type semiconductor layer is set to 85 to 120 degrees.

### TECHNICAL FIELD

The present invention relates to a semiconductor device and a method for manufacturing the semiconductor device.

### BACKGROUND ART

Glass passivated mesa diodes with negative bevel termination structures have been manufactured because of their easiness in production. In spite of their easiness in production, the mesa diodes with the negative bevel termination structures have following disadvantages. Since a surface electric field intensity of the semiconductor substrate is high, it is difficult to increase a withstand voltage as compared with a positive bevel termination structure, and it is also difficult to improve a reverse surge resistance. Moreover, since the deep and wide trench and an expensive wafer with a high specific resistance is required for a higher withstand voltage design at the negative bevel termination structure, their cost increase is inevitable. The reason why the deep and wide trench is required is that forming of trench on a semiconductor substrate by wet etching using a chemical agent requires an extra area (ineffective area) for immersing the chemical agent and releasing air bubbles generated by a chemical reaction. Furthermore, since the higher withstand voltage design requires the deeper and wider trench, the ineffective area increases, which reduces an effective region on a chip. Patent literature 1 discloses related arts.

On the other hand, the mesa diodes with the positive bevel termination structures enables to provide the higher withstand voltage design because of their low surface electric field intensity of the semiconductor substrates, which improves the reverse surge withstand resistance. However, since their PN junction planes are located at a deep portion of the mesa diode structures, the wide and deep trench is required, which causes the large manufacturing variation by etching process. Therefore, it is difficult to manufacture the mesa diodes with the positive bevel termination structures by the conventional art. The mesa diode with the positive bevel termination structure which can provide the higher withstand voltage design and the easiness in production is required.

### CITATION LIST

### Patent Literature

Patent literature 1: WO2014/155739

### SUMMARY OF INVENTION

### Technical Problem

Aspects of the present invention are directed to provide a semiconductor device having a higher withstand voltage design which can be easily manufactured, and to a method for manufacturing the semiconductor device.

### Solution to Problem

The aspects of the present invention will be described below.

[1] A semiconductor device comprising:

a mesa diode structure in which a P-type semiconductor layer, a first N-type semiconductor layer, and a second N-type semiconductor layer having a higher impurity concentration than the first N-type semiconductor layer are laminated in this order; and

a protective layer arranged on a side wall around the mesa diode structure seen in a plane;

wherein the protective layer is not arranged on a lower side surface of the P-type semiconductor layer,

the protective layer is arranged on an upper side surface of the P-type semiconductor layer,

the protective layer is arranged on side surfaces of the first N-type semiconductor layer and the second N-type semiconductor layer, and

a bevel angle formed by a PN junction plane formed between the P-type semiconductor layer and the first N-type semiconductor layer and the upper side surface of the P-type semiconductor layer is 85 degrees or more and 120 degrees or less.

The semiconductor device according to item [1], wherein an angle formed by a junction plane formed between the first N-type semiconductor layer and the second N-type semiconductor layer and a side surface of a junction portion formed between the first N-type semiconductor layer and the second N-type semiconductor layer is 85 degrees or more and 95 degrees or less.

[3] The semiconductor device according to item [1] or [2], wherein a distance between the lower side surface of the P-type semiconductor layer and the side surface of the second N-type semiconductor layer is 50 μm or more and 150 μm or less.

[4] A method for manufacturing a semiconductor device, comprising the steps of:

(a) preparing a semiconductor substrate in which a P-type semiconductor layer, a first N-type semiconductor layer and a second N-type semiconductor layer having a higher impurity concentration than the first N-type semiconductor layer are laminated in this order;

(b c) forming a trench on the semiconductor substrate by cutting the semiconductor substrate using a dicing blade, the trench having a depth from the second N-type semiconductor layer to a part of the P-type semiconductor layer;

(e) applying a glass frit or a material including the glass frit inside the trench;

(f) forming a glass layer inside the trench by baking the glass frit or the material including the glass frit;

(h) forming a first electrode on a top surface of the second N-type semiconductor layer located next the trench; and

(i) dividing the semiconductor substrate by cutting the glass layer and the P-type semiconductor layer along a center of a bottom portion of the trench using a third dicing blade;

wherein a bevel angle formed by a PN junction plane formed between the P-type semiconductor layer and the first N-type semiconductor layer and the upper side surface of the P-type semiconductor layer at the trench is 85 degrees or more and 120 degrees or less,

an angle formed by a junction plane formed between the first N-type semiconductor layer and the second N-type semiconductor layer and a side surface of a junction portion formed between the first N-type semiconductor layer and the second N-type semiconductor layer at the trench is 85 degrees or more and 95 degrees or less, and

the third dicing blade has a width narrower than the width of the dicing blade.

[5] The method for manufacturing the semiconductor device according to item [4], wherein an outer peripheral end of the dicing blade has the width narrower than the width of an inner portion of the dicing blade.

[6] The method for manufacturing the semiconductor device according to item [4],

wherein the step (b c) comprises the steps of:

(b) forming a first trench having the depth from the second N-type semiconductor layer to the part of the P-type semiconductor layer on the semiconductor substrate by cutting the semiconductor substrate using a first dicing blade; and

(c) forming a second trench having the depth from the second N-type semiconductor layer to a part of the first N-type semiconductor layer on the semiconductor substrate by cutting the semiconductor substrate using a second dicing blade, the second trench overlapping the first trench;

wherein the second dicing blade has the width wider than the width of the first dicing blade.

[7] The method for manufacturing the semiconductor device according to any one of items [4] to [6], further comprising the steps of:

(d) forming desired thin films on each of a bottom surface of the trench, a side surface of the trench, and the top surface of the second N-type semiconductor layer between the step (b c) and the step (e); and

(g) removing the desired thin film on the top surface of the second N-type semiconductor layer between the step (f) and the step (h).

[8] The method for manufacturing the semiconductor device according to item [7],

further comprising the steps of:

forming etching protective films on the top surface of the second N-type semiconductor layer and a bottom surface of the P-type semiconductor layer, respectively, between the step (a) and the step (b c); and

etching an inner surface of the trench while masking the top surface of the second N-type semiconductor layer and the bottom surface of the P-type semiconductor layer by the etching protective films and then removing the etching protective films between the step (b c) and the step (d).

[9] The method for manufacturing the semiconductor device according to item [7] or [8], further comprising the step of performing a sandblasting process on the top surface of the second N-type semiconductor layer and the bottom surface of the P-type semiconductor layer, between the step (g) and the step (h).

The method for manufacturing the semiconductor device according to any one of items [4] to [9], wherein the first electrode formed on the top surface of the second N-type semiconductor layer in the step (h) is a first Ni plating layer.

The method for manufacturing the semiconductor device according to any one of items [4] to [9], wherein a second electrode is formed on the bottom surface of the P-type semiconductor layer in addition to the first electrode formed on the top surface of the second N-type semiconductor layer in the step(h), the first electrode is the first Ni plating layer, and the second electrode is a second Ni plating layer.

[12] The method for manufacturing the semiconductor device according to any one of items [4] to [9], wherein the first electrode formed on the top surface of the second N-type semiconductor layer in the step (h) is a first metal electrode formed by a deposition method or a sputtering method.

[13] The method for manufacturing the semiconductor device according to any one of items [4] to [9], wherein the second electrode is formed on the bottom surface of the P-type semiconductor layer in addition to the first electrode formed on the top surface of the second N-type semiconductor layer in the step(h), the first electrode is the first metal electrode formed by the deposition method or the sputtering method, and the second electrode is the second metal electrode formed by the deposition method or the sputtering method,

### Advantageous Effects of Invention

The aspects of the present invention provide a semiconductor device having a higher withstand voltage design which can be easily manufactured, and to a method for manufacturing the semiconductor device.

### BRIEF DESCRIPTION OF DRAWINGS

FIG. 1 is a plane view of a semiconductor device according to an aspect of the present invention.

FIG. 2 is a cross-sectional view of the semiconductor devise shown in FIG. 1.

FIG. 3 is a cross-sectional view illustrating a method for manufacturing the semiconductor device according to an aspect of the present invention.

FIG. 4 is a cross-sectional view illustrating the method for manufacturing the semiconductor device according to an aspect of the present invention.

FIG. 5 is a cross-sectional view illustrating the method for manufacturing the semiconductor device according to an aspect of the present invention.

FIG. 6 is a cross-sectional view illustrating the method for manufacturing semiconductor device according to an aspect of the present invention.

FIG. 7 is a cross-sectional view illustrating the method for manufacturing the semiconductor device according to an aspect of the present invention.

FIG. 8 is a cross-sectional view illustrating the method for manufacturing semiconductor device according to an aspect of the present invention.

FIG. 9 is a cross-sectional view illustrating the method for manufacturing the semiconductor device according to an aspect of the present invention.

FIG. 10 is a cross-sectional view corresponding to FIG. 2, showing another shape of a side wall 20a around a mesa diode structure 20 in FIG. 2.

FIG. 11 is a cross-sectional view illustrating a formation of trenches for the semiconductor device according to an aspect of the present invention.

### DESCRIPTION OF EMBODIMENTS

Detailed embodiments of the present invention will be described below by using appended drawings. However, it will be apparent to those skilled in the art that the present invention is not limited to the following description and the detailed embodiments can be variously modified without departing from the gist and scope of the present invention. Therefore, the present invention should not be interpreted as being limited to the description of the embodiment modes to be given below.

### First Embodiment

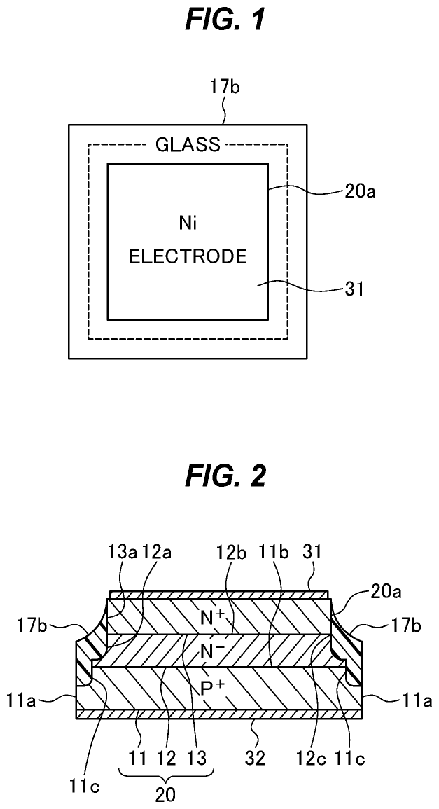

FIG. 1 is a plane view of a semiconductor device according to an aspect of the present invention. FIG. 2 is a cross-sectional view of the semiconductor devise shown in FIG. 1.

The semiconductor device according to the above [1] according to an aspect of the present invention includes a mesa diode structure 20 and a protective layer 17b. The mesa diode structure 20 includes, from bottom to top in sequence, a P-type semiconductor layer 11, a first N-type semiconductor layer 12, and a second N-type semiconductor layer 13 having a higher impurity concentration than the impurity concentration of the first N-type semiconductor layer 12. The protective layer 17b is arranged on a side wall 20a around the mesa diode structure 20 seen in a plane. More specifically, the protective layer 17b is arranged on an upper side surface He of the P-type semiconductor layer 11 and on side surfaces 12a, 13a of the first N-type semiconductor layer 12 and the second N-type semiconductor layer 13, but is not arranged on a lower side surface of the P-type semiconductor layer 11. A bevel angle 30 formed by a PN junction plane 11b formed between the P-type semiconductor layer 11 and the first N-type semiconductor layer12 and the upper side surface lie of the P-type semiconductor layer 11 is 85 degrees or more and 120 degrees or less.

The details will be described below.

The semiconductor device shown in FIG. 1 and FIG. 2 includes the mesa diode structure 20. The mesa diode structure 20 includes, from bottom to top in sequence, the P-type semiconductor layer 11, the first N-type semiconductor layer 12, and the second N-type semiconductor layer 13 having the higher impurity concentration than the impurity concentration of the first N-type semiconductor layer 12. The P-type semiconductor layer 11, the first N-type semiconductor layer 12, and the second N-type semiconductor layer 13 may be formed of silicon.

As shown in FIG. 1, the protective layer 17b is arranged on the side wall 20a around the mesa diode structure 20 seen in a plane. The protective layer 17b is a glass layer.

As shown in FIG. 2, the protective layer 17b is not arranged on the lower side surface of the P-type semiconductor layer 11. In other words, a part of the lower side surface of the P-type semiconductor layer 11 of the mesa diode structure 20 is not covered by the protective layer (glass layer) 17b.

On the other hand, the protective layer 17b is arranged on the upper side surface 11c of the P-type semiconductor layer 11.

The protective layer 17b is arranged on side surfaces 12a, 13a of the first N-type semiconductor layer 12 and the second N-type semiconductor layer 13. In other words, an entire area of the side surfaces 12a, 13a of the first N-type semiconductor layer 12 and the second N-type semiconductor layer 13 is covered by the protective layer (glass layer) 17b.

The bevel angle 30 formed by the PN junction plane 11b formed between the P-type semiconductor layer 11 and the first N-type semiconductor layer 12 and the upper side surface 11c of the P-type semiconductor layer 11 is 85 degrees or more and 120 degrees or less (see FIG. 10).

Although the larger bevel angle 30 causes a stronger electric field buffering effect on the surface (silicon surface) of the first N-type semiconductor layer 12, which provides a higher withstand voltage design, since the bevel angle 30 of larger than 120 degrees increases an ineffective area, which reduces an effective region on a chip, an upper limit of the bevel angle 30 is set to 120 degrees in this embodiment. On the other hand, since the bevel angle 30 of around 90 degrees enables to provide the high withstand voltage mesa diode having the reduced ineffective area, a lower limit of the bevel angle 30 is set to 85 degrees.

A method for manufacturing the semiconductor device shown in FIGS. 1 and 2 will be described later.

FIG. 10 is a cross-sectional view corresponding to FIG. 2, showing another shape of the side wall 20a around the mesa diode structure 20 in FIG. 2. Although a trench is formed by two times of dicing in the method for manufacturing the semiconductor device shown in FIG. 2, the trench is formed by one time of dicing firs the method for manufacturing the semiconductor device shown in FIG. 10.

An angle 40 formed by a junction plane 12b formed between the first N-type semiconductor layer 12 and the second N-type semiconductor layer 13 and a side surface of a junction portion 12c formed between the first N-type semiconductor layer 12 and the second N-type semiconductor layer 13 is preferably 85 degrees or more and 95 degrees or less (see FIG. 10). Most desirably, the angle 40 should be set to 90 degrees. However, the angle may he set to 85 degrees to 95 degrees considering an allowable range of manufacturing variation.

The angle 40 of around 90 degrees enables to reduce a distance 19 between the lower side surface 11a of the P-type semiconductor layer 11 and the side surface 13a of the second N-type semiconductor layer 13 in this embodiment (see FIG. 10). This allows to manufacture the mesa diode by forming the deep and narrow trench on a silicon wafer, which can reduce the ineffective area on the silicon wafer.

The distance 19 between the lower side surface 11a of the P-type semiconductor layer 11 and the side surface 13a of the second N-type semiconductor layer 13 is preferably 50 μm or more and 150 μm or less (see FIG. 10). This allows to manufacture the mesa diode by forming the deep and narrow trench on the silicon wafer, which can reduce the ineffective area on the silicon wafer.

### Second Embodiment

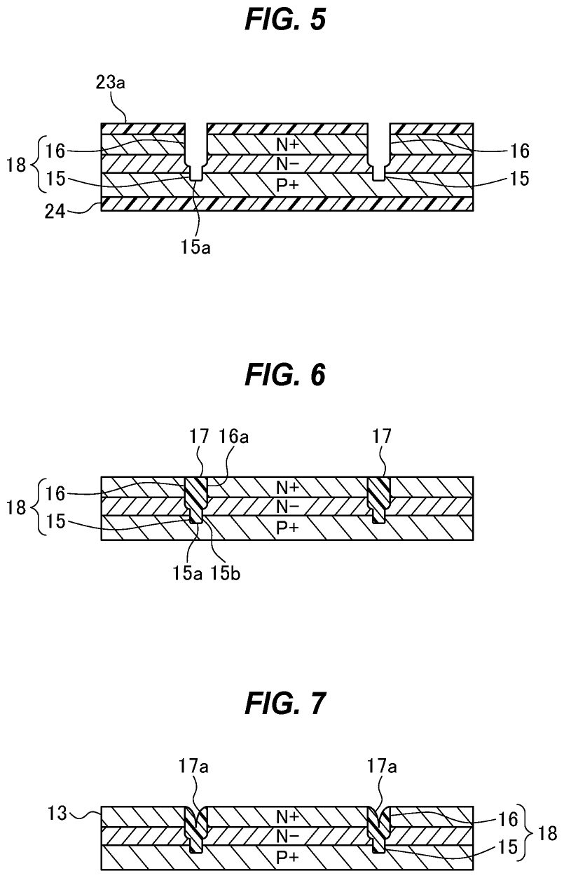

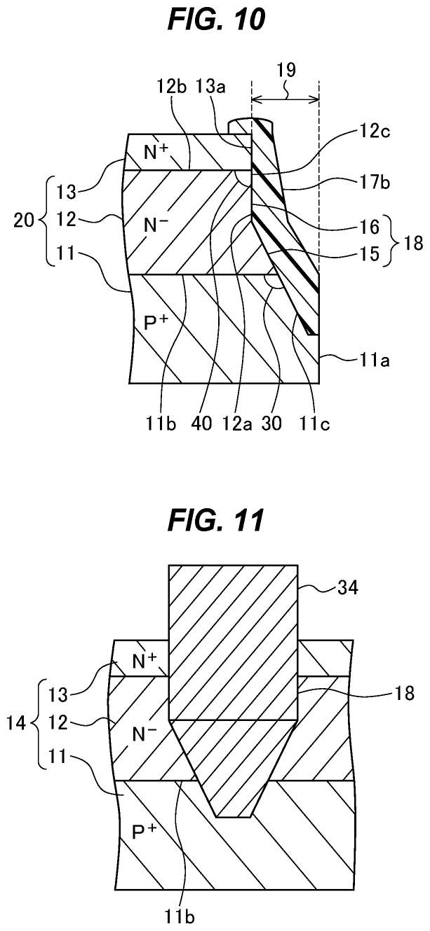

FIG. 11 and FIGS. 5 to 9 are cross-sectional views illustrating a method for manufacturing the semiconductor device shown in FIGS. 1, 2 or FIG. 10. FIG. 10 is a cross-sectional view illustrating a part of a structure of a semiconductor chip after a trench 18 is formed using a dicing blade 34 shown in FIG. 11.

The method for manufacturing a semiconductor device according to the above [4] according to an aspect of the present invention includes the steps of:

(a) preparing a semiconductor substrate (wafer) 14 in which a P-type semiconductor layer 11, a first N-type semiconductor layer 12 and a second N-type semiconductor layer 13 having a higher impurity concentration than impurity concentration of the first N-type semiconductor layer 12 are laminated in this order;

(b c) forming the trench 18 having a depth from the second N-type semiconductor layer 13 to a part of the P-type semiconductor layer 11 on the semiconductor substrate 14 by cutting the semiconductor substrate 14 using the dicing blade 34;

(e) applying a glass frit or a material including the glass frit 17 inside the trench 18;

(f) forming a glass layer 17a inside the trench 18 by baking the glass frit or the material including the glass frit 17;

(h) forming a first electrode 31 on a top surface of the second N-type semiconductor layer 13 located next to the trench 18; and

(i) dividing the semiconductor substrate 14 by cutting the glass layer 17a and the P-type semiconductor layer 11 along a center of a bottom portion 15a of the trench 18 using a third dicing blade 23.

A bevel angle 30 formed by a PN junction plane 11b formed between the P-type semiconductor layer 11 and the first N-type semiconductor layer 12 and the upper side surface 11c of the P-type semiconductor layer 11 at the trench 18 is 85 degrees or more and 120 degrees or less.

An angle formed by a junction plane 12b formed between the first N-type semiconductor layer 12 and the second N-type semiconductor layer 13 and a side surface of a junction portion 12c formed between the first N-type semiconductor layer 12 and the second N-type semiconductor layer 13 at the trench 18 is 85 degrees or more and 95 degrees or less.

The third dicing blade 23 has a width narrower than the width of the dicing blade 34.

As shown in FIG. 11, the semiconductor substrate (wafer) 14 is prepared (step (a)). The semiconductor substrate 14 includes, from bottom to top in sequence, the P-type semiconductor layer (P⁺) 11, the first N-type semiconductor layer (N⁻) 12, and the second N-type semiconductor layer (N⁺) 13 having the higher impurity concentration than the impurity concentration of the first N-type semiconductor layer 12.

Then, as shown in FIG. 11, the trench 18 having the depth from the second N-type semiconductor layer 13 to the part of the P-type semiconductor layer 11 is formed on the semiconductor substrate 14 by cutting the semiconductor substrate 14 using the dicing blade 34 (step (b c)). The dicing blade 34 enables to form the narrow and deep trench, which results in reducing an ineffective area at the trench. In addition, as shown in FIG. 11, since an arbitrary angle is selectable on a top end of the dicing blade 34, a positive bevel termination structure can be implemented, Since the trench is formed by a wet etching process in a conventional manufacturing method, the manufacturing variation of the depth of the trench, the width of the trench, or the bevel angle is large and the wide trench is required for immersing an etching liquid and releasing air bubbles generated by a chemical reaction. However, the trench formed by the dicing blade reduces the manufacturing variation, which enables to manufacture the chip having a shape close to a designed value. In addition, an electric field buffering on the surface caused by the positive bevel termination structure allows to provide the chip having a higher withstand voltage design using an inexpensive wafer with low resistance.

Moreover, as shown in FIG. 11, since the trench is formed from a N surface, i.e. the top surface of the second N-type semiconductor layer 13, using the dicing blade, the positive bevel termination structure can be implemented, which can provide the electric field buffering on the surface. On the other hand, since the trench formed from a P surface by the dicing blade results in a negative bevel termination structure, the electric field buffering effect on the surface is not provided.

Although the trench 18 is formed on the semiconductor substrate 14 by cutting the semiconductor substrate 14 using the dicing blade 34 in this embodiment, since a similar trench can be formed by a laser processing or a dry etching process, same effect can be achieved by the laser processing or the dry etching process.

Then, as shown in FIG. 5, the wet etching process is performed on the silicon inside the trench 18. The wet etching process avoids a damage caused by the dicing blade 34, laser processing, or a dry etching process.

Then, as shown in FIG, 6, the glass frit or a material including the glass frit 17 is applied inside the trench 18 (step (e)). Although a glass paste mixing the grass powder with a vehicle is used in this embodiment, the method applying a resist-glass mixture material mixing the grass powder with a resist liquid or the method applying the glass frit by an electrophoretic deposition can be also used.

Moreover, when the glass layer 17a remains on a portion on which the electrode is formed on the top surface of the second N-type semiconductor layer (N⁺) 13 located next to the trench 18, a protective film is preferably formed on the portion on which the electrode is formed before the step (e), then remove the protective film after the step (e). The protective film prevents the glass layer 17a from remaining on the portion on which the electrode is formed on the top surface of the second N-type semiconductor layer (N⁺) 13.

Then, as shown in FIG. 7, the glass layer 17a as a protective layer inside the trench 18 is formed by baking the glass frit or the material including the glass frit 17 (step (f)). When using the material mixing the glass frit with the vehicle or the resist liquid, the step of baking the material including the glass frit is preferably performed after removing organic substances by burning or decomposing.

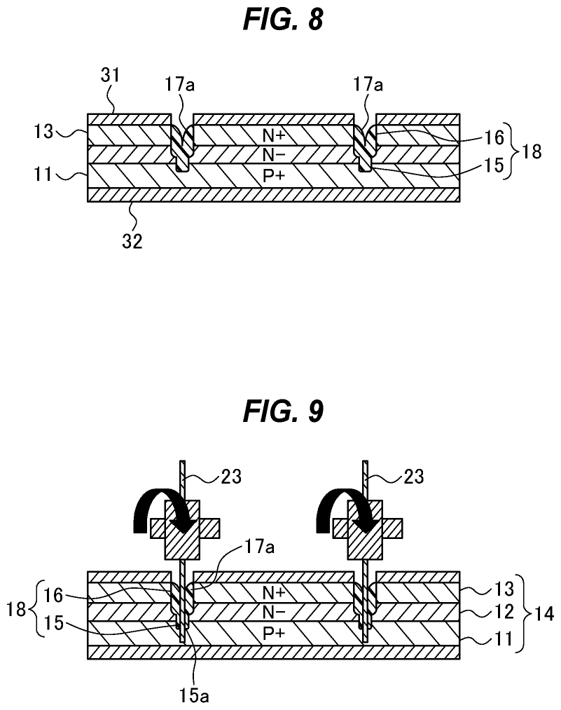

Then, as shown in FIG. 8, the first electrode 31 is formed on the top surface of the second N-type semiconductor layer 13 located next to the trench 18 (step (h)).

Then, as shown in FIG. 9, the semiconductor substrate 14 is divided by cutting the glass layer 17a and the P-type semiconductor layer 11 along the center of the bottom portion 15a of the trench 18 using the third dicing blade 23 (step (i)),

The detailed method may include the step of:

half-cutting the semiconductor substrate 14 using the third dicing blade 23 and then dividing the semiconductor substrate 14 into chips by a breaking process;

attaching a tape (not shown) to the bottom surface (the bottom surface of P-type semiconductor layer 11) of the semiconductor substrate 14 before the step (i) and then dividing the semiconductor substrate 14 into chips by the complete dicing process; or

forming a trench for dividing into chips on the semiconductor substrate 14 in a direction from the bottom surface of the P-type semiconductor layer 11 to the center of the trench 18 using a laser and then dividing the semiconductor substrate 14 into chips by a breaking process.

In these cases, the glass layer 17a functions as the protective layer

The bevel angle 30 formed by the PN junction plane 11b formed between the P-type semiconductor layer 11 and the first N-type semiconductor layer 12 and the upper side surface 11c of the P-type semiconductor layer 11 at the trench 18 is 85 degrees or more and 120 degrees or less (see FIG. 10).

Although the larger bevel angle 30 causes the stronger electric field buffering effect on the surface (silicon surface) of the first N-type semiconductor layer 12 which provides the higher withstand voltage design, since the bevel angle 30 of larger than 120 degrees increases the ineffective area, which reduces an effective region on a chip, an upper limit of the bevel angle 30 is set to 120 degrees in this embodiment. On the other hand, since the bevel angle 30 of around 90 degrees enables to provide the high withstand voltage mesa diode having the reduced ineffective area, a lower limit of the bevel angle 30 is set to 85 degrees.

The angle 40 formed by the junction plane 12b formed between the first N-type semiconductor layer 12 and the second N-type semiconductor layer 13 and the side surface of the junction portion 12c formed between the first N-type semiconductor layer 12 and the second N-type semiconductor layer 13 at the trench 18 is preferably 85 degrees or more and 95 degrees or less. The angle 40 in the above range enables to reduce a distance 19 between the lower side surface 11a of the P-type semiconductor layer 11 and the side surface 13a of the second N-type semiconductor layer 13 (see FIG. 10). Since the trench 18 is formed by the dicing blade, the distance 19 can be reduced. This allows to manufacture the mesa diode by forming the deep and narrow trench on a silicon wafer, which can reduce the ineffective area on the silicon wafer.

The third dicing blade 23 shown in FIG. 9 has preferably the width narrower than the width of the dicing blade 34 shown in FIG. 11. This allows the glass layer 17a as the protective layer to remain on the side wall 20a of the mesa diode structure 20.

As shown in FIG. 11, the outer peripheral end of the dicing blade 34 has preferably the width narrower than the width of the inner portion of the dicing blade 34. This enables the dicing blade 34 to form the trench 18 having a shape shown in FIG. 10. The dicing blade 34 in FIG. 11 shows an example of forming the trench 18 by one time of dicing in the above step (b c). FIG. 11 shows only a vicinity of the outer peripheral end of the dicing blade 34.

Moreover, an angle of the outer peripheral end of the dicing blade 34 is preferably set to 0 degrees to 30 degrees. This enables the bevel angle 30 shown in FIG. 10 to be set to 90 degrees to 120 degrees. The lower limit of the bevel angle 30 may be 85 degrees considering an allowable range of manufacturing variation.

Although the trench 18 is formed on the semiconductor substrate 14 by cutting the semiconductor substrate 14 using the dicing blade 34, since a similar trench can he formed by the laser processing or the dry etching process, same effect can be achieved by the laser processing or the dry etching process,

### Third Embodiment

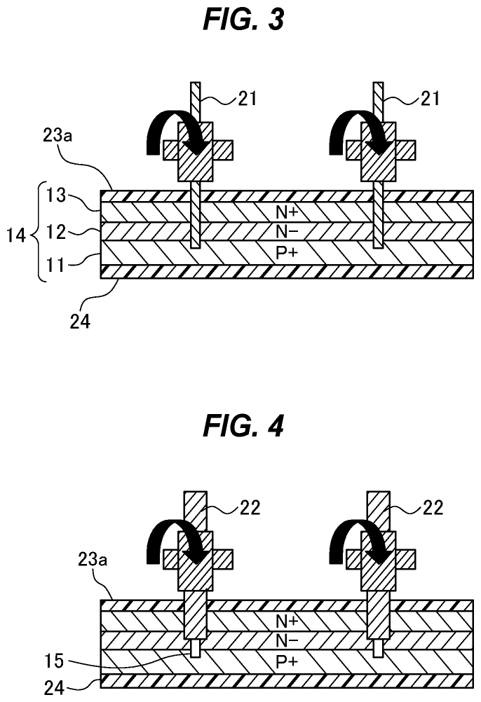

The dicing blade 34 shown in FIG. 11 forms the trench 18 by one time of dicing in the above step (b c) in Embodiment 2. On the other hand, Embodiment 3 describes an example in which the dicing blades 21, 22 shown in FIGS. 3 and 4 form the trench 18 by two times of dicing in the step (b) and the step (c) below.

The step (b c) may include the step (b) and the step (c)

As shown in FIG. 3, the first trench 15 having the depth from the top surface of the semiconductor substrate 14, i.e. the top surface of the second N-type semiconductor layer 13, to the part of the P-type semiconductor layer 11 is formed on the semiconductor substrate 14 by cutting the semiconductor substrate 14 using the first dicing blade 21 (step (b)).

Although the first trench 15 having the depth from the top surface of the semiconductor substrate 14 to the part of the P-type semiconductor layer 11 is formed on the semiconductor substrate 14 by cutting the semiconductor substrate 14 using the first dicing blade 21 in this embodiment, since a similar trench of the first trench can be formed by the laser processing or the dry etching process, same effect can be achieved by the laser processing or the dry etching process.

Then, as shown in FIG. 4, the second trench 16 having the depth from the top surface of the semiconductor substrate 14, i.e. the top surface of the second N-type semiconductor layer 13, to the part of the first N-type semiconductor layer (N⁻) 12 is formed on the semiconductor substrate 14 by cutting the semiconductor substrate 14 using the second dicing blade 22 so that the second trench 16 overlaps the first trench 15 (step (c)). The second trench 16 is formed by cutting the semiconductor substrate 14 using the second dicing blade 22 while aiming along the center of the bottom portion 15a of the first trench 15 shown in FIG. 5.

Although the second trench 16 having the depth from the top surface of the semiconductor substrate 14 t the part of the first N-type semiconductor layer (N⁻) 12 is formed on the semiconductor substrate 14 by cutting the semiconductor substrate 14 using the second dicing blade 22 so that the second trench 16 overlaps the first trench 15, since a similar trench of the second trench can be formed by the laser processing or the dry etching process, same effect can be achieved by the laser processing or the dry etching process.

Then, as shown in FIG. 5, the wet etching process is performed on the silicon of the inner surfaces of the first trench 15 and the second trench 16 (i.e. each of the bottom surface 15a of the first trench 15, the side surface 15b of the first trench 15, the side surface 16a of the second trench 16, and the top surface of the second N-type semiconductor layer 13). This allows to avoid damages caused by cutting the semiconductor substrate 14 using the first dicing blade 21 and the second dicing blade 22, respectively.

Although the step (c) is performed after the step (b) in this embodiment, the order may be reversed such that the step (b) is performed after the step (c).

The second dicing blade 22 has the wider width than the width of the first dicing blade 21. This enables to form a trench integrating the first trench 15 and the second trench 16 as shown in FIG, 5,

Moreover, as shown in FIGS. 5 and 6, desired thin films (not shown) may be formed on each of the bottom surface 15a of the trench 18, the side surfaces 15b, 16a of the trench 18, and the top surface of the second N-type semiconductor layer 13 between the step (b c) and the step (e), More specifically, the desired thin films (not shown) may be formed on each of the bottom surface 15a of the first trench 15, the side surface 15b of the first trench 15, the side surface 16a of the second trench 16, and the top surface of the second N-type semiconductor layer 13 (step (d)). The desired thin films are preferably thin films such as an oxidized film on the surface, SIPOS (Semi-Insulated Polycrystalline Silicon), and a nitride film. Forming these thin films enables to provide a desired diode characteristics and a long-term reliability.

As shown in FIGS. 7 and 8, the desired thin film on the top surface of the second N-type semiconductor layer 13 is removed (step (g)) between the step (f) and the step (h).

As shown in FIG. 3, the etching protective films 23a, 24 is formed on the top surface of the second N-type semiconductor layer 13 and a bottom surface of the P-type semiconductor layer 11, respectively, between the step (a) and the step (b c), The etching protective films 23a, 24 may be formed of an organic film, the resist, or the oxidized film, etc, The protective films 23a, 24 allow to reduce damages such as a chipping and a clack caused by dicing in addition to the protection from the etching liquid.

As shown in FIG. 5, the inner surface of the trench 18 is etched while masking the top surface of the second N-type semiconductor layer 13 and the bottom surface of the P-type semiconductor layer 11 by the etching protective films 23a, 24 and then removing the etching protective films 23a, 24 between the step (b c) and the step (e). The etching of the inner surface of the trench 18 enables to avoid damages caused by dicing. An etching amount of the inner surface of the trench 18 is preferably around 30 μm. When the etching amount is small, such as 5pm or less, the etching process may be performed after removing the protective films.

As shown in FIGS. 7 and 8, the step of performing a sandblasting process (a process splaying an abrasive) on the top surface of the second N-type semiconductor layer 13 and the bottom surface of the P-type semiconductor layer 11 is preferably included between the step (g) and the step (h), The sandblasting process enables to form fine irregularities on the top surface of the second N-type semiconductor layer 13 and the bottom surface of the P-type semiconductor layer 11.

The first electrode 31 formed on the top surface of the second N-type semiconductor layer 13 in the step (h) is preferably a first Ni plating layer (see FIG. 8). Although the first Ni plating layer as the first electrode 31 is formed on the top surface of the second N-type semiconductor layer 13 in the step (h), the protective film (not shown) for protecting the glass layer 17a may be formed on the glass layer 17a before forming the first Ni plating layer, and then the first Ni plating layer may be formed. As described above, the fine irregularities formed on the top surface of the second N-type semiconductor layer 13 improve an adhesion of the first Ni plating layer.

A second electrode 32 is formed on the bottom surface of the P-type semiconductor layer 11 in addition to the first electrode 31 formed on the top surface of the second N-type semiconductor layer 13 in the step(h). The first electrode 31 is preferably the first Ni plating layer; and the second electrode 32 is preferably a second Ni plating layer (see FIG. 8). The protective film (not shown) for protecting the glass layer 17a is preferably formed on the glass layer 17a before forming the first Ni plating layer and the second Ni plating layer, and then the first Ni plating layer and the second Ni plating layer are formed. As described above, the fine irregularities formed on the top surface of the second N-type semiconductor layer 13 and on the bottom surface of the P-type semiconductor layer 11 improve the adhesions of the first Ni plating layer and the second Ni plating layer.

The first electrode 31 formed on the top surface of the second N-type semiconductor layer 13 in the step (h) may be a first metal electrode formed by a deposition method or a sputtering method, The first metal electrode is preferably an Al layer or a Ti/Ni laminate. Although the first metal electrode as the first electrode 31 is formed on the top surface of the second N-type semiconductor layer 13 in the step (h), the protective film (not shown) for protecting the glass layer 17a may be formed on the glass layer 17a before forming the first metal electrode, and then the Al layer or the Ti/Ni laminate may be formed by the deposition method or the sputtering method, The first metal electrode enables to connect by a soldering or a bonding.

The second electrode 32 is formed on the bottom surface of the P-type semiconductor layer 11 in addition to the first electrode 31 formed on the top surface of the second N-type semiconductor layer 13 in the step(h), the first electrode may be the first metal electrode formed by the deposition method or the sputtering method, and the second electrode may be the second metal electrode formed by the deposition method or the sputtering method. Each of the first metal electrode and the second metal electrode is preferably the Al layer or the Ti/Ni laminate. Although the first metal electrode as the first electrode 31 is formed on the top surface of the second N-type semiconductor layer 13 and the second metal electrode as the second electrode 32 is formed on the bottom surface of the P-type semiconductor layer 11 in the step (h), the protective film (not shown) for protecting the glass layer 17a is preferably formed on the glass layer 17a before forming the first metal electrode and the second metal electrode, and then the Al layers or the Ti/Ni laminates is formed by the deposition method or the sputtering method. The first metal electrode and the second metal electrode enable to connect by the soldering or the bonding.

### EXPLANATION OF SYMBOLS

11 P-type semiconductor layer

11a lower side surface of P-type semiconductor layer

11b PN junction plane

11c upper side surface of P-type semiconductor layer

12 first N-type semiconductor layer

12a side surface of first N-type semiconductor layer

12b junction plane formed between first N-type semiconductor layer and second N-type semiconductor layer

12c side surface of junction portion formed between first N-type semiconductor layer and second N-type semiconductor layer

13 second N-type semiconductor layer

13a side surface of second N-type semiconductor layer

14 semiconductor substrate (wafer)

15 first trench

15a bottom portion of first trench

15b, 16a side surface of trench

16 second trench

17 glass frit or material including glass frit

17a glass layer

17b protective layer

18 trench

19 distance between lower side surface of P-type semiconductor layer and side surface of second N-type semiconductor layer

20 mesa diode structure

20a side wall around mesa diode structure

21 first dicing blade

22 second dicing blade

23 third dicing blade

23a, 24 etching protective film

30 bevel angle

31 first electrode

32 second electrode

34 dicing blade

40 angle

1. A semiconductor device comprising:
a mesa diode structure in which a P-type semiconductor layer, a first N-type semiconductor layer, and a second N-type semiconductor layer having a higher impurity concentration than the first N-type semiconductor layer are laminated in this order; and
a protective layer arranged on a side wall around the mesa diode structure seen in a plane;
wherein the protective layer is not arranged on a lower side surface of the P-type semiconductor layer,
the protective layer is arranged on an upper side surface of the P-type semiconductor layer,
the protective layer is arranged on side surfaces of the first N-type semiconductor layer and the second N-type semiconductor layer, and
a bevel angle formed by a PN junction plane formed between the P-type semiconductor layer and the first N-type semiconductor layer and the upper side surface of the P-type semiconductor layer is 85 degrees or more and 120 degrees or less.

2. The semiconductor device according to claim 1, wherein an angle formed by a junction plane formed between the first N-type semiconductor layer and the second N-type semiconductor layer and a side surface of a junction portion formed between the first N-type semiconductor layer and the second N-type semiconductor layer is 85 degrees or more and 95 degrees or less.

3. The semiconductor device according to claim 1, wherein a distance between the lower side surface of the P-type semiconductor layer and the side surface of the second N-type semiconductor layer is 50 μm or more and 150 μm or less.

4. A method for manufacturing a semiconductor device, comprising the steps of:
(a) preparing a semiconductor substrate in which a P-type semiconductor layer, a first N-type semiconductor layer and a second N-type semiconductor layer having a higher impurity concentration than the first N-type semiconductor layer are laminated in this order;
(b c) forming a trench on the semiconductor substrate by cutting the semiconductor substrate using a dicing blade, the trench having a depth from the second N-type semiconductor layer to a part of the P-type semiconductor layer;
(e) applying a glass frit or a material including the glass frit inside the trench;
(f) forming a glass layer inside the trench by baking the glass frit or the material including the glass frit;
(h) forming a first electrode on a top surface of the second N-type semiconductor layer located next the trench; and
(i) dividing the semiconductor substrate by cutting the glass layer and the P-type semiconductor layer along a center of a bottom portion of the trench using a third dicing blade;
wherein a bevel angle formed by a PN junction plane formed between the P-type semiconductor layer and the first N-type semiconductor layer and the upper side surface of the P-type semiconductor layer at the trench is 85 degrees or more and 120 degrees or less,
an angle formed by a junction plane formed between the first N-type semiconductor layer and the second N-type semiconductor layer and a side surface of a junction portion formed between the first N-type semiconductor layer and the second N-type semiconductor layer at the trench is 85 degrees or more and 95 degrees or less, and
the third dicing blade has a width narrower than the width of the dicing blade.

5. The method for manufacturing the semiconductor device according to claim 4, wherein an outer peripheral end of the dicing blade has the width narrower than the width of an inner portion of the dicing blade.

6. The method for manufacturing the semiconductor device according to claim 4,
wherein the step (b c) comprises the steps of:
(b) forming a first trench having the depth from the second N-type semiconductor layer to the part of the P-type semiconductor layer on the semiconductor substrate by cutting the semiconductor substrate using a first dicing blade; and
(c) forming a second trench having the depth from the second N-type semiconductor layer to a part of the first N-type semiconductor layer on the semiconductor substrate by cutting the semiconductor substrate using a second dicing blade, the second trench overlapping the first trench;
wherein the second dicing blade has the width wider than the width of the first dicing blade.

7. The method for manufacturing the semiconductor device according to claim 4, further comprising the steps of:
(d) forming desired thin films on each of a bottom surface of the trench, a side surface of the trench, and the top surface of the second N-type semiconductor layer between the step (b c) and the step (e); and
(g) removing the desired thin film on the top surface of the second N-type semiconductor layer between the step (f) and the step (h).

8. The method for manufacturing the semiconductor device according to claim 7,
further comprising the steps of:
forming etching protective films on the top surface of the second N-type semiconductor layer and a bottom surface of the P-type semiconductor layer, respectively, between the step (a) and the step (b c); and
etching an inner surface of the trench while masking the top surface of the second N-type semiconductor layer and the bottom surface of the P-type semiconductor layer by the etching protective films and then removing the etching protective films between the step (b c) and the step (d).

9. The method for manufacturing the semiconductor device according to claim 7, further comprising the step of performing a sandblasting process on the top surface of the second N-type semiconductor layer and the bottom surface of the P-type semiconductor layer, between the step (g) and the step (h).

10. The method for manufacturing the semiconductor device according to claim 4, wherein the first electrode formed on the top surface of the second N-type semiconductor layer in the step (h) is a first Ni plating layer.

11. The method for manufacturing the semiconductor device according to claim 4, wherein a second electrode is formed on the bottom surface of the P-type semiconductor layer in addition to the first electrode formed on the top surface of the second N-type semiconductor layer in the step(h), the first electrode is the first Ni plating layer, and the second electrode is a second Ni plating layer.

12. The method for manufacturing the semiconductor device according to claim 4, wherein the first electrode formed on the top surface of the second N-type semiconductor layer in the step (h) is a first metal electrode formed by a deposition method or a sputtering method.

13. The method for manufacturing the semiconductor device according to claim 4, wherein the second electrode is formed on the bottom surface of the P-type semiconductor layer in addition to the first electrode formed on the top surface of the second N-type semiconductor layer in the step(h), the first electrode is the first metal electrode formed by the deposition method or the sputtering method, and the second electrode is the second metal electrode formed by the deposition method or the sputtering method.
